(19) United States
(12) Patent Application Publication
(10) Pub. No.: US 2025/0343168 A1
(43) Pub. Date: Nov. 6, 2025

(54) SEMICONDUCTOR DEVICE

(71) Applicant: ROHM CO., LTD., Kyoto-shi (JP)

(72) Inventors: Akinori NII, Kyoto-shi (JP); Kenji FUJII, Kyoto-shi (JP); Bin ZHANG, Kyoto-shi (JP)

(21) Appl. No.: 19/273,673

(22) Filed: Jul. 18, 2025

Related U.S. Application Data
(63) Continuation of application No. PCT/JP2024/000256, filed on Jan. 10, 2024.

(30) Foreign Application Priority Data
Jan. 25, 2023 (JP) 2023-009199

(51) Int. Cl. H01L 23/00; H01L 23/31; H01L 23/495

(52) U.S. Cl. CPC H01L 23/562; H01L 23/3114; H01L 23/4951; H01L 24/16; H01L 2224/16175; H01L 2924/35121

(57) ABSTRACT

A semiconductor device includes: a semiconductor element; a lead; a bonding target; a conductive bonding material that electrically bonds the bonding target and the lead; and a sealing resin that covers the bonding target and the lead. The lead includes a lead body including an obverse surface facing the bonding target, and a metal layer disposed on the obverse surface. A material of the metal layer has better wettability to the conductive bonding material in a molten state than a material of the lead body. The conductive bonding material is bonded to the metal layer. The obverse surface includes an uneven region spaced apart from the metal layer in plan view, and a smooth region located between the metal layer and the uneven region.

### TECHNICAL FIELD

The present disclosure relates to a semiconductor device.

### BACKGROUND ART

Various configurations have been proposed for a semiconductor device including a semiconductor element. JP-A-2020-77694 discloses an example of a conventional semiconductor device. The semiconductor device disclosed in JP-A-2020-77694 includes a plurality of leads, a semiconductor element, and a sealing resin. The semiconductor element is supported by the leads. The semiconductor device employs a flip-chip mounting method where electrodes of the semiconductor element are bonded to the leads with solder. Parts of the leads are covered with the sealing resin.

### BRIEF DESCRIPTION OF THE DRAWINGS

FIG. 1 is a perspective view showing a semiconductor device according to a first embodiment of the present disclosure.

FIG. 2 is a plan view showing the semiconductor device according to the first embodiment of the present disclosure.

FIG. 3 is a bottom view showing the semiconductor device according to the first embodiment of the present disclosure.

FIG. 4 is a front view showing the semiconductor device according to the first embodiment of the present disclosure.

FIG. 5 is a right-side view showing the semiconductor device according to the first embodiment of the present disclosure.

FIG. 6 is a cross-sectional view taken along line VI-VI in FIG. 2.

FIG. 7 is a cross-sectional view taken along line VII-VII in FIG. 2.

FIG. 8 is a cross-sectional view taken along line VIII-VIII in FIG. 2.

FIG. 9 is a partially enlarged plan view showing the semiconductor device according to the first embodiment of the present disclosure.

FIG. 10 is a partially enlarged cross-sectional view taken along line X-X in FIG. 9.

FIG. 11 is a partially enlarged plan view showing the semiconductor device according to the first embodiment of the present disclosure.

FIG. 12 is a partially enlarged cross-sectional view taken along line XII-XII in FIG. 11.

FIG. 13 is a partially enlarged plan view showing a first variation of the semiconductor device according to the first embodiment of the present disclosure.

FIG. 14 is a partially enlarged plan view showing a second variation of the semiconductor device according to the first embodiment of the present disclosure.

FIG. 15 is a partially enlarged plan view showing a third variation of the semiconductor device according to the first embodiment of the present disclosure.

FIG. 16 is a partially enlarged cross-sectional view showing a fourth variation of the semiconductor device according to the first embodiment of the present disclosure.

FIG. 17 is a partially enlarged cross-sectional view showing a fifth variation of the semiconductor device according to the first embodiment of the present disclosure.

FIG. 18 is a partially enlarged cross-sectional view showing a semiconductor device according to a second embodiment of the present disclosure.

FIG. 19 is a partially enlarged cross-sectional view showing a semiconductor device according to a third embodiment of the present disclosure.

### DETAILED DESCRIPTION OF EMBODIMENTS

The following describes preferred embodiments of the present disclosure in detail with reference to the drawings.

The terms such as “first”, “second” and “third” in the present disclosure are used merely for identification, and are not intended to impose orders on the elements accompanied with these terms.

In the present disclosure, the phrases “an object A is formed in an object B” and “an object A is formed on an object B” include, unless otherwise specified, “an object A is formed directly in/on an object B” and “an object A is formed in/on an object B with another object interposed between the object A and the object B”. Similarly, the phrases “an object A is disposed in an object B” and “an object A is disposed on an object B” include, unless otherwise specified, “an object A is disposed directly in/on an object B” and “an object A is disposed in/on an object B with another object interposed between the object A and the object B”. Similarly, the phrase “an object A is located on an object B” includes, unless otherwise specified, “an object A is located on an object B in contact with the object B” and “an object A is located on an object B with another object interposed between the object A and the object B”. Further, the phrase “an object A overlaps with an object B as viewed in a certain direction” includes, unless otherwise specified, “an object A overlaps with the entirety of an object B” and “an object A overlaps with a part of an object B”. Further, the phrase “a plane A faces (a first side or a second side) in a direction B” is not limited to the case where the angle of the plane A with respect to the direction B is 90°, but also includes the case where the plane A is inclined to the direction B.

### First Embodiment

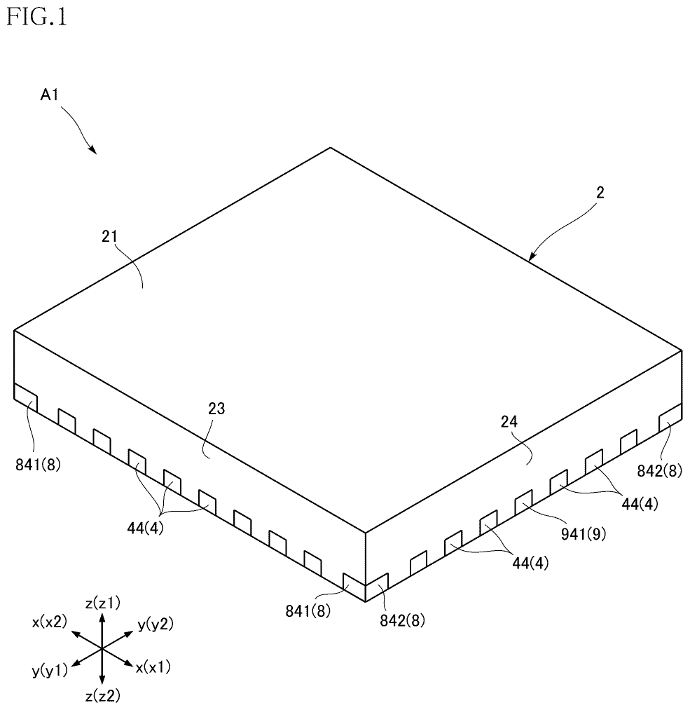

FIGS. 1 to 12 show a semiconductor device according to a first embodiment of the present disclosure. A semiconductor device A1 of the present embodiment includes a semiconductor element 1, a sealing resin 2, and a plurality of leads 4, 8, and 9. The semiconductor device A1 is provided in a quad flat no-lead (QFN) package, but the basic configuration of the semiconductor device of the present disclosure is not particularly limited.

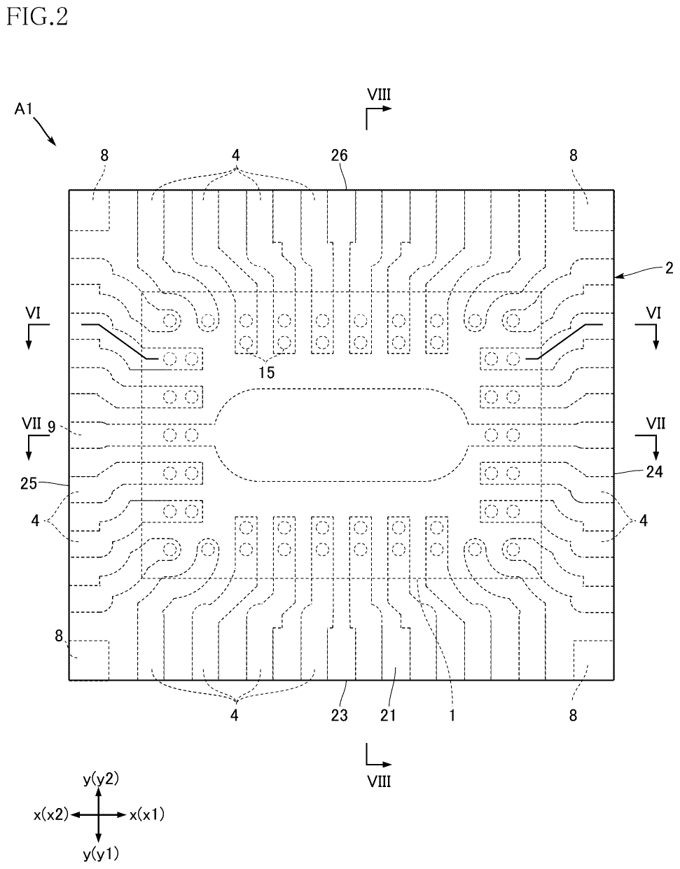

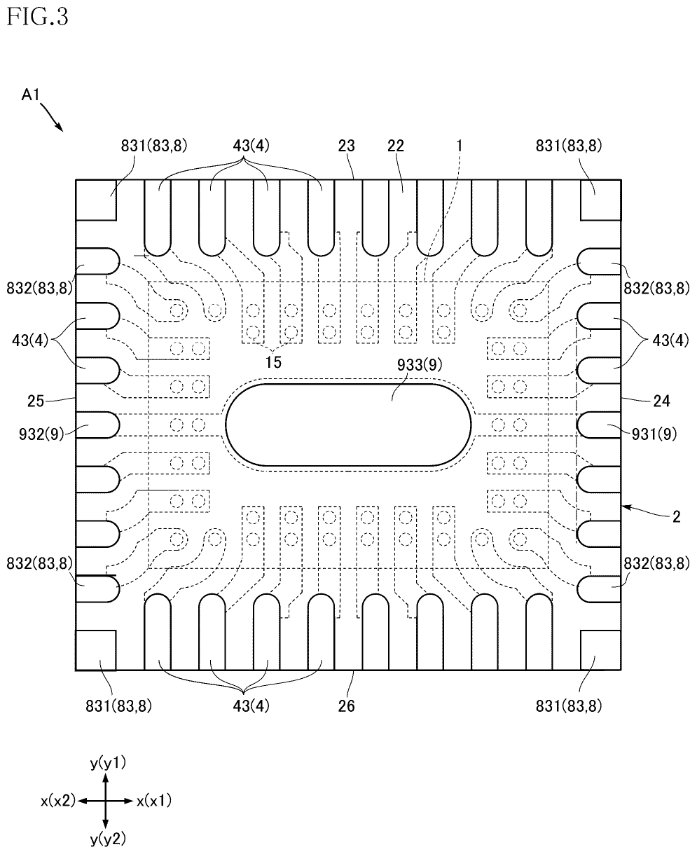

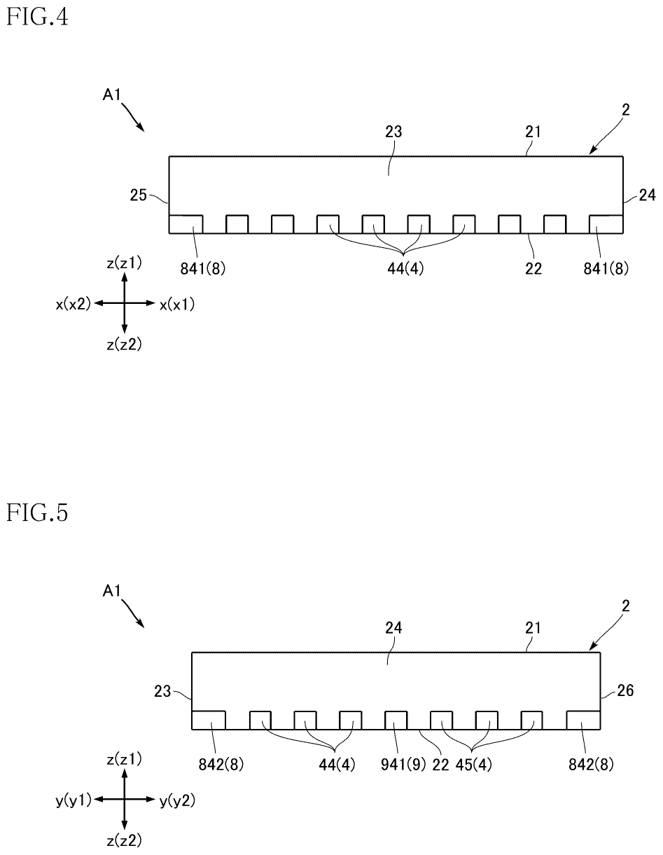

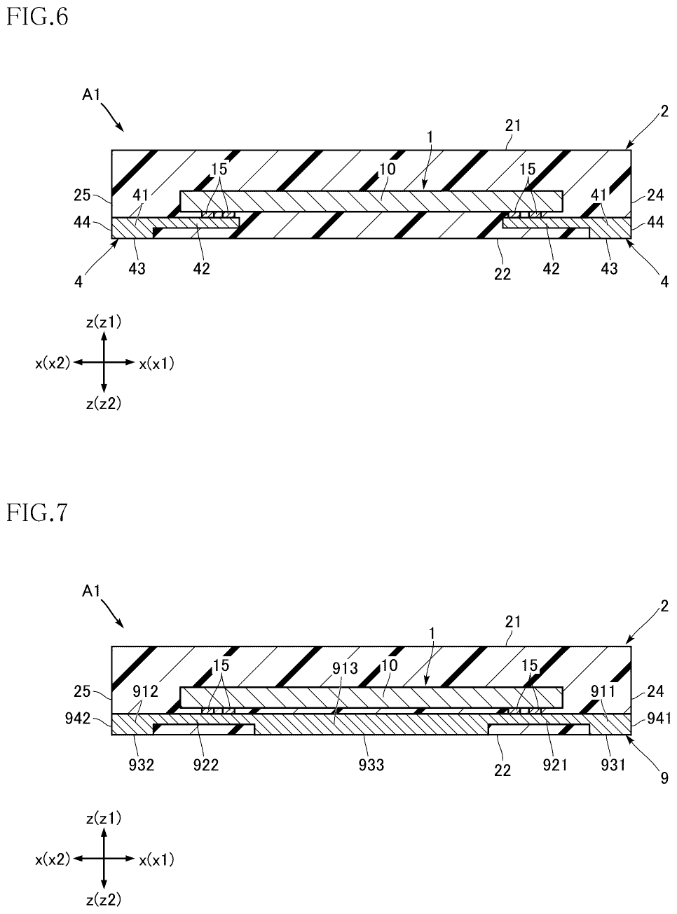

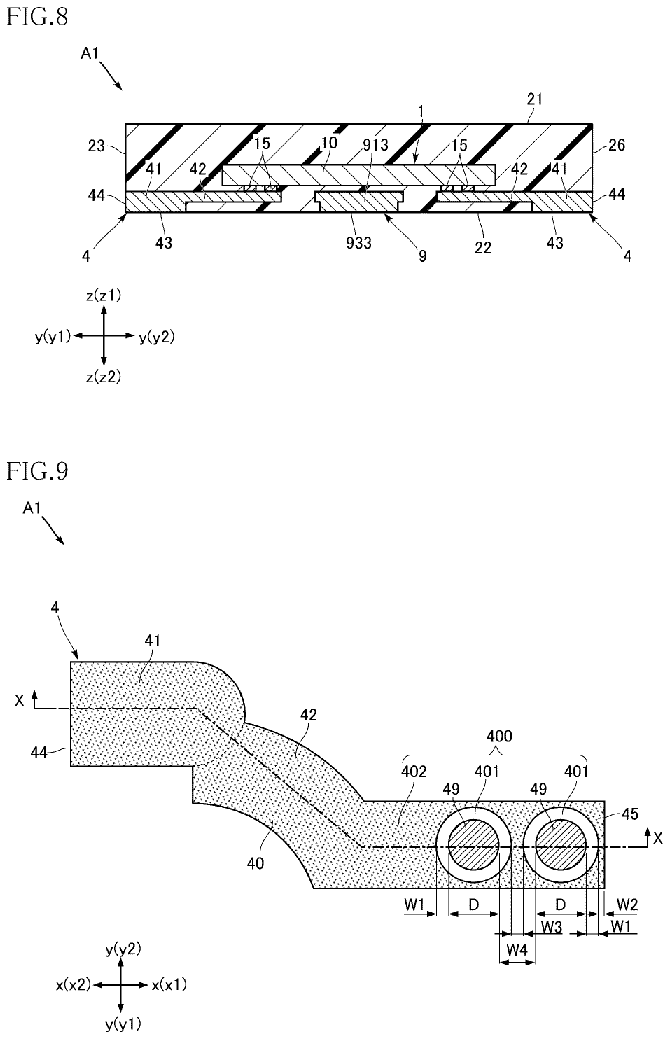

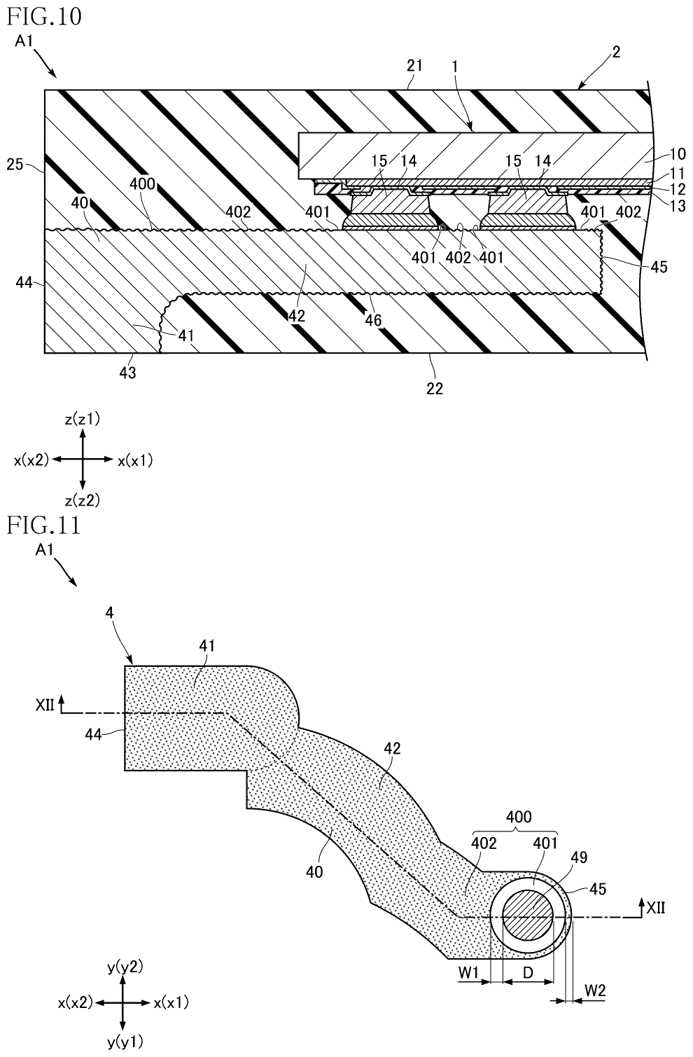

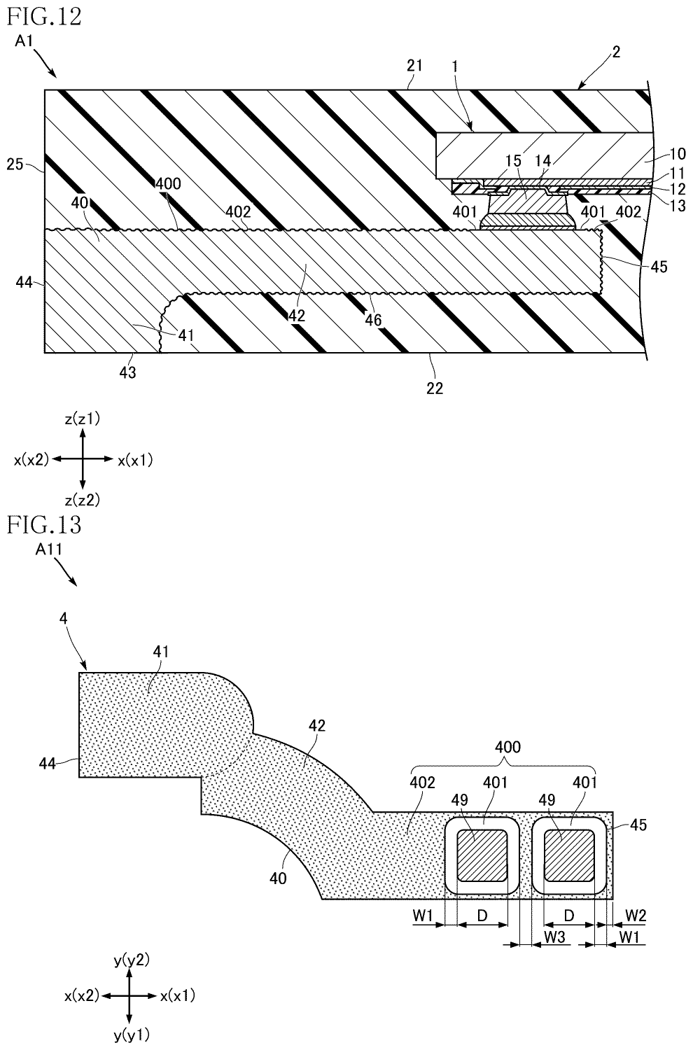

FIG. 1 is a perspective view showing the semiconductor device A1. FIG. 2 is a plan view showing the semiconductor device A1. FIG. 3 is a bottom view showing the semiconductor device A1. FIG. 4 is a front view showing the semiconductor device A1. FIG. 5 is a right-side view showing the semiconductor device A1. FIG. 6 is a cross-sectional view taken along line VI-VI in FIG. 2. FIG. 7 is a cross-sectional view taken along line VII-VII in FIG. 2. FIG. 8 is a cross-sectional view taken along line VIII-VIII in FIG. 2. FIG. 9 is a partially enlarged plan view showing the semiconductor device A1. FIG. 10 is a partially enlarged cross-sectional view taken along line X-X in FIG. 9. FIG. 11 is a partially enlarged plan view showing the semiconductor device A1. FIG. 12 is a partially enlarged cross-sectional view taken along line XII-XII in FIG. 11.

In these figures, the thickness direction of the semiconductor element 1 is referred to as a thickness direction z. In the present disclosure, “plan view” is synonymous with “as viewed in the thickness direction z”. A direction perpendicular to the thickness direction z is referred to as a first direction x. The direction perpendicular to the thickness direction z and the first direction x is referred to as a second direction y.

### Semiconductor Element 1:

The semiconductor element 1 performs main electrical functions of the semiconductor device A1 when the semiconductor device A1 is mounted on a circuit board or the like to form a part of an electrical circuit. The semiconductor element 1 is not particularly limited to a specific configuration, and may be a large scale integration (LSI) circuit or an integrated circuit (IC), for example. The semiconductor element 1 of the present embodiment has a rectangular shape having two sides extending in the first direction x and two sides extending in the second direction y as viewed in the thickness direction z.

As shown in FIGS. 2, 3, 6 to 8, 10, and 12, the semiconductor element 1 has an element body 10 and a plurality of electrodes 15. The element body 10 is a portion that includes a semiconductor material such as silicon (Si), and has a functional circuit (not illustrated) built therein, for example.

The electrodes 15 are provided to flip-chip mount the semiconductor element 1 onto the leads 4 and 9. Each electrode 15 is an example of a bonding target in the present disclosure. The electrodes 15 protrude from the element body 10 to a z2 side in the thickness direction z. The material of the electrodes 15 is not particularly limited, and may contain a metal such as copper (Cu) or a copper (Cu) alloy. The tip of each electrode 15 on the z2 side in the thickness direction z may be provided with a plating layer (not illustrated) that contains nickel (Ni) as appropriate.

In the illustrated example, the semiconductor element 1 has a wiring layer 11, a first protective layer 12, a second protective layer 13, and an underlying layer 14. The wiring layer 11 is disposed on the element body 10 on the z2 side in the thickness direction z. The wiring layer 11 is electrically connected to the functional circuit (not illustrated) in the element body 10. The wiring layer 11 contains aluminum (A1), for example. The first protective layer 12 covers the wiring layer 11 from the z2 side in the thickness direction z. The first protective layer 12 contains silicon nitride (SiN), for example. The first protective layer 12 is formed with an opening through which a part of the wiring layer 11 is exposed. The second protective layer 13 covers the first protective layer 12 from the z2 side in the thickness direction z. The second protective layer 13 contains polyimide, for example. The second protective layer 13 is formed with an opening that overlaps with the opening of the first protective layer 12. The underlying layer 14 is provided to cover the opening of the second protective layer 13. The second protective layer 13 contains copper (Cu) or nickel (Ni), for example. The electrodes 15 are formed by growing a metal on the second protective layer 13 by plating, for example.

### Sealing Resin 2:

The sealing resin 2 covers the semiconductor element 1 and a part of each of the leads 4, 8, and 9. The sealing resin 2 is not particularly limited to a specific configuration, and may be made of a material containing epoxy resin. As shown in FIGS. 1 to 8, the sealing resin 2 of the present embodiment has a resin obverse surface 21, a resin reverse surface 22, a first resin side surface 23, a second resin side surface 24, a third resin side surface 25, and a fourth resin side surface 26.

The resin obverse surface 21 faces a z1 side in the thickness direction z. In the illustrated example, the resin obverse surface 21 is a flat surface having a rectangular shape. The resin reverse surface 22 faces the z2 side in the thickness direction z. In the illustrated example, the resin reverse surface 22 is a flat surface having a rectangular shape. The first resin side surface 23 is a surface along the first direction x and the thickness direction z, and faces a y1 side in the second direction y. The second resin side surface 24 is a surface along the second direction y and the thickness direction z, and faces an x1 side in the first direction x. The third resin side surface 25 is a surface along the second direction y and the thickness direction z, and faces an x2 side in the first direction x. The fourth resin side surface 26 is a surface along the first direction x and the thickness direction z, and faces a y2 side in the second direction y.

In the present embodiment, the length of each of the first resin side surface 23 and the fourth resin side surface 26 in the first direction x is longer than the length of each of the second resin side surface 24 and the third resin side surface 25 in the second direction y.

The leads 4, 8, and 9 have the functions of supporting the semiconductor element 1 and forming the conductive paths to the semiconductor element 1, for example. The specific configurations of the leads 4, 8, and 9 are not particularly limited. The leads 4, 8, and 9 are made of a material containing any of copper (Cu), nickel (Ni), iron (Fe), and alloys of these metals, for example. In the following description, the leads 4, 8, and 9 are distinguished as a plurality of leads 4, a plurality of corner leads 8, and a center lead 9.

### Leads 4:

As shown in FIGS. 1 to 12, the leads 4 are aligned in the first direction x and the second direction y, and are disposed to form a rectangular shape. Each of the leads 4 has a lead body 40 and a metal layer 49. FIGS. 9 and 10 show the second lead 4 counted from the y2 side in the second direction y, among the leads 4 arranged on the x2 side in the first direction x in FIG. 2. FIGS. 11 and 12 show the first lead 4 counted from the y2 side in the second direction y, among the leads 4 arranged on the x2 side in the first direction x in FIG. 2. FIGS. 9 and 11 omit the semiconductor element 1 and the sealing resin 2 to facilitate understanding.

The lead body 40 forms a large part of the lead 4, and may be made of a material containing any of copper (Cu), nickel (Ni), iron (Fe), and alloys of these metals, as described above. The lead body 40 has an obverse surface 400, a thick portion 41, a thin portion 42, a mounting surface 43, an end surface 44, a side surface 45, and an intermediate surface 46.

The thick portion 41 is a portion of the lead 4 that is relatively thick in the thickness direction z (as compared to the thin portion 42). The thin portion 42 is a portion of the lead 4 that is relatively thin in the thickness direction z (as compared to the thick portion 41). The respective shapes of the thick portion 41 and the thin portion 42 as viewed in the thickness direction z are set appropriately according to, for example, the position at which the semiconductor element 1 is mounted.

The obverse surface 400 faces the z1 side in the thickness direction z. The obverse surface 400 faces an electrode 15 of the semiconductor element 1. The obverse surface 400 extends on both the thick portion 41 and the thin portion 42. The obverse surface 400 is covered with the sealing resin 2.

The mounting surface 43 is a surface of the thick portion 41, and is exposed from the resin reverse surface 22 of the sealing resin 2. In the illustrated example, the mounting surface 43 is flush with the resin reverse surface 22.

The end surface 44 is exposed from the first resin side surface 23, the second resin side surface 24, the third resin side surface 25, or the fourth resin side surface 26 of the sealing resin 2, and faces in the first direction x or the second direction y. The end surface 44 is a surface of the thick portion 41. In the illustrated example, the mounting surface 43 and the end surface 44 are connected to each other. It is possible to form a recessed surface or the like between the mounting surface 43 and the end surface 44. Each of the mounting surface 43 and the end surface 44 may be provided with a plating layer (not illustrated) that contains tin (Sn), for example, as appropriate. In the illustrated example, the end surface 44 is flush with one of the first resin side surface 23, the second resin side surface 24, the third resin side surface 25, and the fourth resin side surface 26.

The side surface 45 faces in a direction intersecting the thickness direction z, and is located between the obverse surface 400 and the intermediate surface 46 in the thickness direction z. The side surface 45 is covered with the sealing resin 2.

The intermediate surface 46 is a surface of the thin portion 42. The intermediate surface 46 is located between the obverse surface 400 and the mounting surface 43 in the thickness direction z and, similarly to the mounting surface 43, faces the z2 side in the thickness direction z. The intermediate surface 46 is covered with the sealing resin 2. The intermediate surface 46 is spaced apart from the resin reverse surface 22 to the z1 side in the thickness direction z.

The metal layer 49 is disposed on the obverse surface 400. The metal layer 49 is a member to which a conductive bonding material 19 is bonded. The material of the metal layer 49 has better wettability to the conductive bonding material 19 in a molten state than the material of the lead body 40. The shape of the metal layer 49 is not particularly limited, and may be selected from various shapes such as a circle, an ellipse, or a polygon. In the illustrated example, the metal layer 49 has a circular shape.

The obverse surface 400 includes a smooth region 401 and an uneven region 402. The uneven region 402 has a surface roughness larger than the smooth region 401. The surface roughness of the uneven region 402 is not particularly limited. Examples of the surface roughness of the uneven region 402 include an arithmetic mean roughness Ra of at least 1 μm and at most 10 μm. The method for forming the uneven region 402 is not particularly limited. For example, the uneven region 402 may be formed through a roughening treatment by etching or a roughening treatment with which CuO or Cu₂O (copper oxide) is grown in a needle shape. The smooth region 401 and the uneven region 402 are covered with the sealing resin 2, and are directly in contact with the sealing resin 2.

In the illustrated example, the side surface 45 and the intermediate surface 46 are uneven surfaces similar to the uneven region 402. The method for forming the end surface 45 and the intermediate surface 46 to be uneven may be the same as that for forming the uneven region 402.

As shown in FIGS. 9 to 12, the uneven region 402 is spaced apart from the metal layer 49 in plan view. The smooth region 401 is located between the metal layer 49 and the uneven region 402 in plan view. In the illustrated example, the smooth region 401 surrounds the entire periphery of the metal layer 49 in plan view, and the uneven region 402 surrounds the entire periphery of the smooth region 401 in plan view.

The uneven region 402 reaches an edge of the obverse surface 400 in plan view. In the illustrated example, the uneven region 402 reaches all edges of the obverse surface 400. The uneven region 402 may reach only a part of an edge of the obverse surface 400, or may not reach any of the edges of the obverse surface 400. The smooth region 401 is spaced apart from the edges of the obverse surface 400. The smooth region 401 may reach the edges of the obverse surface 400.

In FIGS. 9 and 11, a dimension D of the metal layer 49 (the diameter of the metal layer 49 in the illustrated example) is at least 50 μm and at most 200 μm, for example, and may be approximately 100 μm. A dimension W1 is the distance between the metal layer 49 and the uneven region 402, and corresponds to the width of the smooth region 401. The dimension W1 is at least 5% and at most 50% of the dimension D, for example.

A dimension W2 is the distance between the smooth region 401 and an edge of the obverse surface 400. In the illustrated example, the dimension W2 is the distance between the smooth region 401 and an end of the obverse surface 400 in the first direction x. The dimension W2 is at least 5% and at most 50% of the dimension D, for example.

In the lead 4 shown in FIGS. 9 and 10, two metal layers 49 are disposed on the obverse surface 400. The metal layers 49 are spaced apart from each other. The obverse surface 400 includes two smooth regions 401. The two smooth regions 401 surround the two metal layers 49, respectively. The uneven region 402 has a portion located between the two metal layers 49 (the two smooth regions 401). A dimension W3 is the distance between the two smooth regions 401 adjacent to each other. The dimension W3 is at least 5% and at most 90% of the dimension D, for example. A dimension W4 is the distance between the adjacent metal layers 49. In the illustrated example, the dimension W4 is smaller than the dimension D.

### Corner Lead 8:

As shown in FIGS. 1 to 5, the corner leads 8 are disposed at the four corners of the sealing resin 2 as viewed in the thickness direction z.

Each of the corner leads 8 has a corner mounting surface 83, a first corner end surface 841, and a second corner end surface 842.

The corner mounting surface 83 faces the z2 side in the thickness direction z, and is exposed from the resin reverse surface 22 of the sealing resin 2.

The first corner end surface 841 faces in the second direction y, and is exposed from the first resin side surface 23 or the fourth resin side surface 26. In the illustrated example, the first corner end surface 841 is flush with the first resin side surface 23 or the fourth resin side surface 26. The second corner end surface 842 faces in the first direction x, and is exposed from the second resin side surface 24 or the third resin side surface 25. In the illustrated example, the second corner end surface 842 is flush with the second resin side surface 24 or the third resin side surface 25. In the illustrated example, the first corner end surface 841 and the second corner end surface 842 are connected to each other.

### Center Lead 9:

As shown in FIGS. 1 to 3, 5, and 7, the center lead 9 is disposed between the leads 4 in the second direction y. In the illustrated example, the center lead 9 overlaps with the center of the semiconductor device A1 (the sealing resin 2) in the second direction y. In the illustrated example, the center lead 9 has a center thick portion 911, a center thick portion 912, a center thick portion 913, a center thin portion 921, a center thin portion 922, a center mounting surface 931, a center mounting surface 932, a center mounting surface 933, a center end surface 941, and a center end surface 942.

The center mounting surface 931, the center mounting surface 932, and the center mounting surface 933 correspond to portions that are thicker than the other portions (the center thin portion 921 and the center thin portion 922) of the center lead 9 in the thickness direction z.

The center thick portion 911 has the center mounting surface 931 and the center end surface 941. The center thick portion 912 has the center mounting surface 932 and the center end surface 942. The center thick portion 913 has the center mounting surface 933. The center thick portion 911 is disposed on the x1 side in the first direction x. The center thick portion 912 is disposed on the x2 side in the first direction x. The center thick portion 913 is disposed at the center in the first direction x.

The center thin portion 921 and the center thin portion 922 are thinner than the other portions (the center thick portion 911, the center thick portion 912, and the center thick portion 913) of the center lead 9 in the thickness direction z, and are spaced apart from the resin reverse surface 22 to the z1 side in the thickness direction z. In the present embodiment, the semiconductor element 1 is mounted on the center thin portion 921 and the center thin portion 922. As shown in FIGS. 2 and 3, in the present embodiment, some of the electrodes 15 of the semiconductor element 1 are electrically bonded to the center lead 9. The electrical bonding between the electrodes 15 and the center lead 9 may be configured in the same manner as the electrical bonding between the electrodes 15 and the leads 4. As with the leads 4, the center lead 9 may be configured to have portions corresponding to the lead body 40 and the metal layer 49. As with the leads 4, the center lead 9 may have a surface having the same configuration as the obverse surface 400 that includes the smooth region 401 and the uneven region 402.

Next, advantages of the semiconductor device A1 will be described.

As shown in FIGS. 9 to 12, the obverse surface 400 includes a smooth region 401 and an uneven region 402. The smooth region 401 surrounds a metal layer 49. The material of the metal layer 49 has better wettability to the conductive bonding material 19 in a molten state than the material of the lead body 40. The smooth region 401 is smoother than the uneven region 402, and has poor wettability to the conductive bonding material 19 in a molten state as compared to the uneven region 402. Thus, in the manufacturing of the semiconductor device A1, the conductive bonding material 19 in a molten state quickly spreads along the metal layer 49 and does not easily spread to the smooth region 401. As a result, the conductive bonding material 19 in a molten state tends to remain on the metal layer 49 and can be prevented from spreading to the smooth region 401. Since the uneven region 402 has recesses and protrusions, the uneven region 402 has a higher adhesion strength with the sealing resin 2 than the smooth region 401. This makes it possible to increase the adhesion strength between the lead 4 and the sealing resin 2. Thus, it is possible to suppress peeling of the sealing resin 2 while maintaining an appropriate bonding state.

When the dimension W1 is at least 5% and at most 50% of the dimension D, it contributes to the suppression of unintended spreading of the conductive bonding material 19 in a molten state and peeling of the sealing resin 2.

The uneven region 402 reaches an edge of the obverse surface 400. This makes it possible to suppress peeling of the sealing resin 2 from the obverse surface 400 at the edge of the obverse surface 400. In the present example, the uneven region 402 reaches all the edges of the obverse surface 400. This contributes to the suppression of peeling of the sealing resin 2.

As shown in FIGS. 10 and 12, the side surface 45 is an uneven surface. Thus, the unevenness is provided in both the uneven region 402 and the side surface 45. This makes it possible to more effectively suppress peeling of the sealing resin 2 at the edge of the obverse surface 400. Since the intermediate surface 46 is uneven, peeling of the sealing resin 2 can be more reliably suppressed.

As shown in FIGS. 9 and 10, a part of the uneven region 402 is located between the two adjacent metal layers 49. This suppresses peeling of the sealing resin 2.

FIGS. 13 to 19 show variations and other embodiments of the present disclosure. In these figures, elements that are the same as or similar to those in the above embodiment are provided with the same reference numerals as in the above embodiment. The configurations of the elements in each variation and each embodiment can be combined as appropriate as long as the combination does not cause technical inconsistency.

### First Variation of First Embodiment

FIG. 13 shows a first variation of the semiconductor device A1. A semiconductor device A11 of the present variation is different from the above example in the shapes, etc., of the electrodes 15, the metal layers 49, and the smooth regions 401.

In the present variation, each the metal layer 49 has a rectangular shape in plan view. The shape of each metal layer 49 corresponds to the shape of each electrode 15 that has a rectangular shape, for example. Each smooth region 401 has the shape of a rectangular ring or frame in plan view. In the present variation, the dimension D may be the length of a side of a metal layer 49, for instance, the size of a metal layer 49 in the first direction x, in which two metal layers 49 are adjacent to each other.

According to the present variation, it is also possible to suppress peeling of the sealing resin 2 while maintaining an appropriate bonding state. As can be understood from the present variation, the shapes of the electrodes 15, the metal layers 49, and the smooth regions 401 are not particularly limited.

### Second Variation of First Embodiment

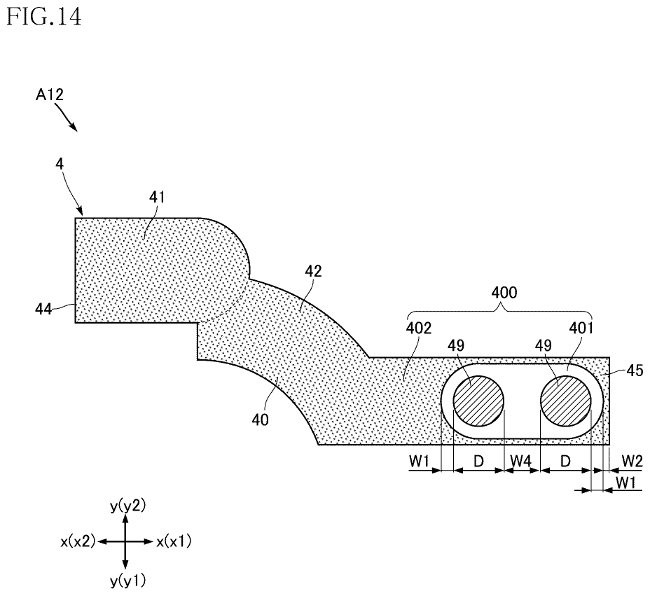

FIG. 14 shows a second variation of the semiconductor device A1. A semiconductor device A12 of the present variation is different from the above example in the shapes of the smooth regions 401 and the uneven regions 402.

In the present variation, a single smooth region 401 surrounds two metal layers 49. In other words, there is no uneven region 402 between adjacent metal layers 49. In the present variation, the dimension W4 may be smaller than the dimension W4 in the semiconductor device A1, and may be half of the dimension D or less.

According to the present variation, it is also possible to suppress peeling of the sealing resin 2 while maintaining an appropriate bonding state. As can be understood from the present variation, the shapes, etc., of the smooth regions 401 and the uneven regions 402 are not particularly limited.

### Third Variation of First Embodiment

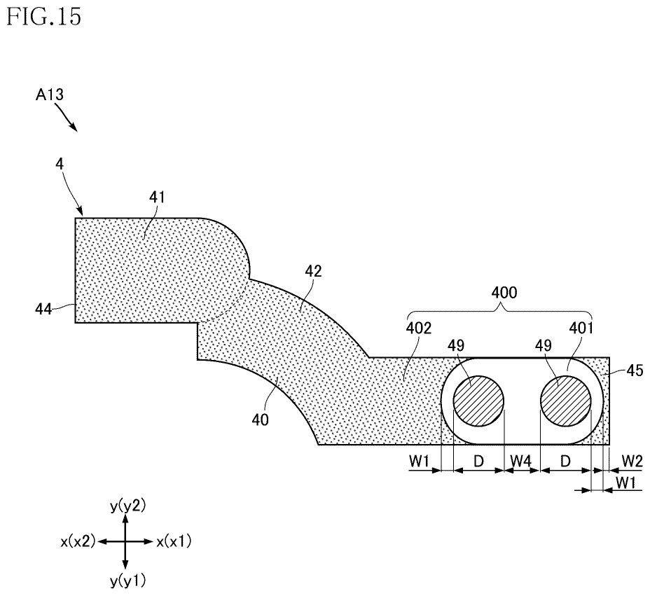

FIG. 15 shows a third variation of the semiconductor device A1. A semiconductor device A13 of the present variation is different from the above example in the shapes of the smooth regions 401 and the uneven regions 402.

In the present variation, each smooth region 401 reaches an edge of an obverse surface 400 in plan view. In other words, a part of an edge of each obverse surface 400 is not in contact with an uneven region 402. The edge of the obverse surface 400 on the x1 side in the first direction x (the edge located on the opposite side from the end surface 44) is in contact with the uneven region 402.

According to the present variation, it is also possible to suppress peeling of the sealing resin 2 while maintaining an appropriate bonding state. As can be understood from the present variation, the shapes, etc., of the smooth regions 401 and the uneven regions 402 are not particularly limited. Since the edge of each obverse surface 400 on the x1 side in the first direction x (the edge located on the opposite side from an end surface 44) is in contact with an uneven region 402, peeling at the interface between the end of the obverse surface 400 on the x1 side in the first direction x and the sealing resin 2 can be suppressed.

### Fourth Variation of First Embodiment

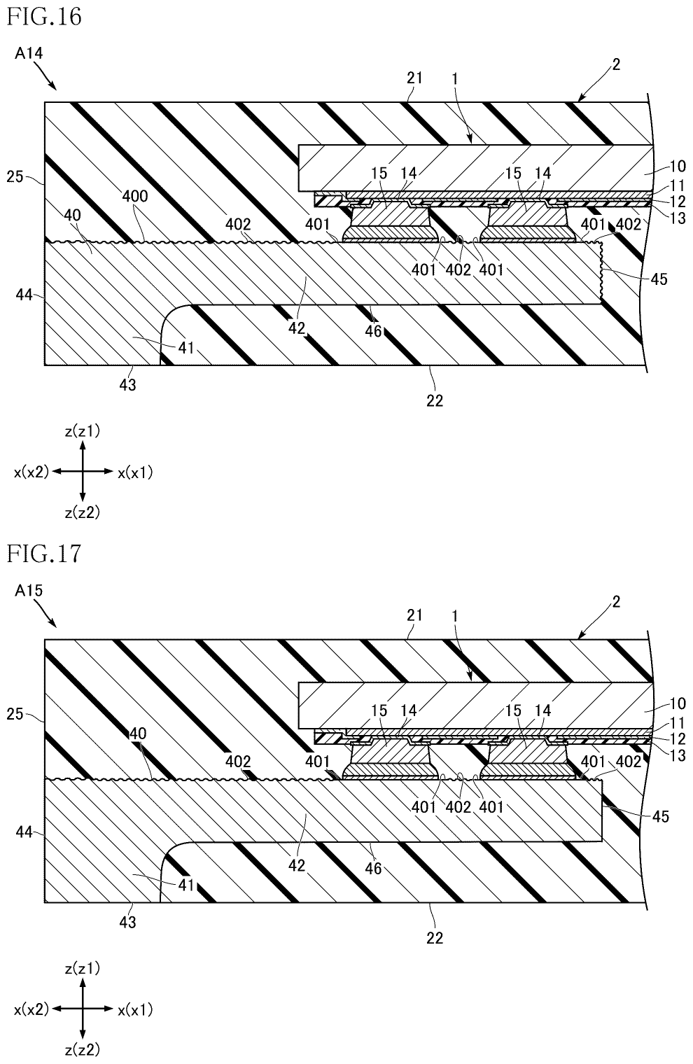

FIG. 16 shows a fourth variation of the semiconductor device A1. A semiconductor device A14 of the present variation is different from the above example in the configuration of each lead 4.

In the present variation, each intermediate surface 46 is a smooth surface as compared to an uneven region 402 and a side surface 45. According to the present variation, it is also possible to suppress peeling of the sealing resin 2 while maintaining an appropriate bonding state. As can be understood from the present variation, each intermediate surface 46 may be a smooth surface.

### Fifth Variation of First Embodiment

FIG. 17 shows a fifth variation of the semiconductor device A1. A semiconductor device A15 of the present variation is different from the above example in the configuration of each lead 4.

In the present variation, each side surface 45 is a smooth surface as compared to an uneven region 402. According to the present variation, it is also possible to suppress peeling of the sealing resin 2 while maintaining an appropriate bonding state. As can be understood from the present variation, each side surface 45 may be a smooth surface.

### Second Embodiment

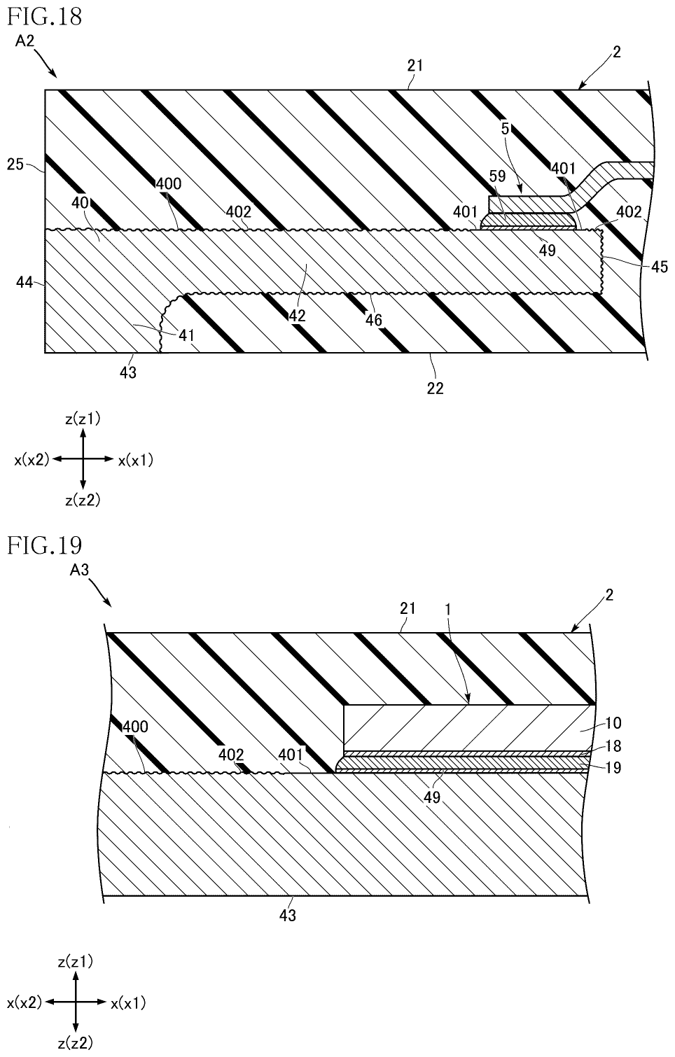

FIG. 18 shows a semiconductor device according to a second embodiment of the present disclosure. A semiconductor device A2 of the present embodiment includes a conductive member 5.

The conductive member 5 may be electrically connected to a semiconductor element 1 (not illustrated), for example. The conductive member 5 may contain copper (Cu), nickel (Ni), iron (Fe), and alloys of these metals, for example. The conductive member 5 is electrically bonded to a metal layer 49 of a lead 4 via a conductive bonding material 59. The conductive member 5 is an example of a bonding target in the present disclosure. The conductive bonding material 59 may have the same configuration as the conductive bonding material 19 described above.

According to the present embodiment, it is also possible to suppress peeling of a sealing resin 2 while maintaining an appropriate bonding state. As can be understood from the present embodiment, a bonding target in the present disclosure is not particularly limited, and may be a member that contains a metal such as the conductive member 5.

### Third Embodiment

FIG. 19 shows a semiconductor device according to a third embodiment of the present disclosure. A semiconductor device A3 of the present embodiment includes a semiconductor element 1, which corresponds to a bonding target in the present disclosure.

The semiconductor element 1 of the present embodiment has a metal layer 18. The metal layer 18 is disposed on an element body 10 on the z2 side in the thickness direction z. The metal layer 18 contains copper (Cu), aluminum (A1), or nickel (Ni), for example.

The metal layer 18 is bonded to a metal layer 49 via a conductive bonding material 19. The conductive bonding material 19 is not particularly limited, and may be a silver (Ag) paste.

According to the present embodiment, it is also possible to suppress peeling of a sealing resin 2 while maintaining an appropriate bonding state. As can be understood from the present embodiment, a bonding target in the present disclosure is not particularly limited, and may be the semiconductor element 1 (the metal layer 18). The conductive bonding material 19 may take various configurations, including solder and a silver (Ag) paste.

The semiconductor device according to the present disclosure is not limited to the embodiments described above. Various design changes can be made to the specific configurations of the elements of the semiconductor device according to the present disclosure. The present disclosure includes the embodiments described in the following clauses.

### Clause 1.

A semiconductor device comprising:
a semiconductor element;
a lead;
a bonding target;
a conductive bonding material that electrically bonds the bonding target and the lead; and
a sealing resin that covers the bonding target and at least a part of the lead,
wherein the lead includes a lead body and a metal layer, the lead body including an obverse surface facing the bonding target, the metal layer being disposed on the obverse surface,
a material of the metal layer has better wettability to the conductive bonding material in a molten state than a material of the lead body,
the conductive bonding material is bonded to the metal layer, and
the obverse surface includes an uneven region spaced apart from the metal layer in plan view, and a smooth region located between the metal layer and the uneven region.

### Clause 2.

The semiconductor device according to clause 1, wherein the semiconductor element includes an electrode that serves as the bonding target.

### Clause 3.

The semiconductor device according to clause 1, wherein a minimum distance between the metal layer and the uneven region in plan view is at least 5% and at most 50% of a dimension of the metal layer.

### Clause 4.

The semiconductor device according to clause 2 or 3, wherein the uneven region reaches an edge of the obverse surface in plan view.

### Clause 5.

The semiconductor device according to clause 4, wherein the lead body includes a side surface oriented to intersect the obverse surface and covered with the sealing resin, and the side surface is uneven.

### Clause 6.

The semiconductor device according to clause 5, wherein the lead body includes a mounting surface facing an opposite side from the obverse surface and exposed from the sealing resin, and an intermediate surface located between the obverse surface and the mounting surface and facing a same side as the mounting surface, and the intermediate surface is uneven.

### Clause 7.

The semiconductor device according to any of clauses 2 to 6, wherein the lead includes two metal layers adjacent to each other, one of which is the metal layer mentioned above.

### Clause 8.

The semiconductor device according to clause 7, wherein the uneven region includes a portion located between the two metal layers.

### Clause 9.

The semiconductor device according to clause 8, wherein a distance between the two metal layers in plan view is smaller than a dimension of the metal layer in plan view.

### Clause 10.

The semiconductor device according to clause 7, wherein the uneven region is not located between the two metal layers.

### Clause 11.

The semiconductor device according to any of clauses 2 to 10, wherein the uneven region surrounds the smooth region.

### Clause 12.

The semiconductor device according to any of clauses 2 to 11, wherein the smooth region is spaced apart from an edge of the obverse surface in plan view.

### Clause 13.

The semiconductor device according to any of clauses 2 to 11, wherein the smooth region is in contact with the edge of the obverse surface in plan view.

### Clause 14.

The semiconductor device according to any of clauses 2 to 13, wherein the conductive bonding material is solder.

### Clause 15.

The semiconductor device according to clause 14, wherein the lead body contains Cu. Clause 16.

The semiconductor device according to clause 15, wherein the metal layer contains Ag. Clause 17.

The semiconductor device according to clause 15, wherein the metal layer contains Ni.

REFERENCE NUMERALS

A1, A11-A15, A2, A3: Semiconductor device 1: Semiconductor element
2: Sealing resin 4: Lead 5: Conductive member (Bonding target)
8: Corner lead 9: Center lead 10: Element body 11: Wiring layer
12: First protective layer 13: Second protective layer 14: Underlying layer
15: Electrode (Bonding target) 18: Metal layer (Bonding target)
19: Conductive bonding material 21: Resin obverse surface 22: Resin reverse surface
23: First resin side surface 24: Second resin side surface 25: Third resin side surface
26: Fourth resin side surface 40: Lead body 41: Thick portion
42: Thin portion 43: Mounting surface 44: End surface 45: Side surface
46: Intermediate surface 49: Metal layer 59: Conductive bonding material
83: Corner mounting surface 400: Obverse surface 401: Smooth region
402: Uneven region 443: End surface 445: End surface 841: First corner end surface
842: Second corner end surface 911-913: Center thick portion
921, 922: Center thin portion 931-933: Center mounting surface
941, 942: Center end surface x: First direction y: Second direction z: Thick direction

1. A semiconductor device comprising:
a semiconductor element;
a lead;
a bonding target;
a conductive bonding material that electrically bonds the bonding target and the lead; and
a sealing resin that covers the bonding target and at least a part of the lead,
wherein the lead includes a lead body and a metal layer, the lead body including an obverse surface facing the bonding target, the metal layer being disposed on the obverse surface,
a material of the metal layer has better wettability to the conductive bonding material in a molten state than a material of the lead body,
the conductive bonding material is bonded to the metal layer, and
the obverse surface includes an uneven region spaced apart from the metal layer in plan view, and a smooth region located between the metal layer and the uneven region.

2. The semiconductor device according to claim 1, wherein the semiconductor element includes an electrode that serves as the bonding target.

3. The semiconductor device according to claim 1, wherein a minimum distance between the metal layer and the uneven region in plan view is at least 5% and at most 50% of a dimension of the metal layer.

4. The semiconductor device according to claim 2, wherein the uneven region reaches an edge of the obverse surface in plan view.

5. The semiconductor device according to claim 4, wherein the lead body includes a side surface oriented to intersect the obverse surface and covered with the sealing resin, and
the side surface is uneven.

6. The semiconductor device according to claim 5, wherein the lead body includes a mounting surface facing an opposite side from the obverse surface and exposed from the sealing resin, and an intermediate surface located between the obverse surface and the mounting surface and facing a same side as the mounting surface, and
the intermediate surface is uneven.

7. The semiconductor device according to claim 2, wherein the lead includes two metal layers adjacent to each other, one of which is the metal layer mentioned above.

8. The semiconductor device according to claim 7, wherein the uneven region includes a portion located between the two metal layers.

9. The semiconductor device according to claim 8, wherein a distance between the two metal layers in plan view is smaller than a dimension of the metal layer in plan view.

10. The semiconductor device according to claim 7, wherein the uneven region is not located between the two metal layers.

11. The semiconductor device according to claim 2, wherein the uneven region surrounds the smooth region.

12. The semiconductor device according to claim 2, wherein the smooth region is spaced apart from an edge of the obverse surface in plan view.

13. The semiconductor device according to claim 2, wherein the smooth region is in contact with an edge of the obverse surface in plan view.

14. The semiconductor device according to claim 2, wherein the conductive bonding material is solder.

15. The semiconductor device according to claim 14, wherein the lead body contains Cu.

16. The semiconductor device according to claim 15, wherein the metal layer contains Ag.

17. The semiconductor device according to claim 15, wherein the metal layer contains Ni.
